(19) United States
(12) Patent Application Publication
(10) Pub. No.: US 2004/0100274 A1
(43) Pub. Date: May 27, 2004

(54) Arc fault tester

(75) Inventors: William Gloster, Stone Mountain, GA (US); Carlos Restrepo, Atlanta, GA (US)

Correspondence Address: Elsa Keller, Siemens Corporation, Intellectual Property Department, 170 Wood Avenue South, Iselin, NJ, 08830, US

(73) Assignee: Siemens Energy & Automation, Inc.

(21) Appl. No.: 10/453,105

(22) Filed: Jun. 3, 2003

Related U.S. Application Data
(60) Provisional application No. 60/428,565, filed on Nov. 22, 2002.

(51) Int. Cl. H01H 9/50; G01R 31/08; G01R 31/12

(52) U.S. Cl. 324/536

(57) ABSTRACT

Arc fault detector device (such as arc fault circuit interrupter) testing apparatus and methods including generating a true arc fault current by energizing a contact relay at a predetermined frequency, applying and regulating the true arc fault current to a detection device under test by selecting a load from a resistor bank that is coupled to the tested device, determining whether the device under test was able to detect the arc fault current. The invention is useful for determining whether an arc fault circuit interrupter is capable of tripping in response to an arc fault current.

### FIELD OF INVENTION

The present invention relates to the testing of devices that protect electrical circuits by recognizing and interrupting an arcing fault and more particularly, to methods and apparatus for testing the operation of an arc fault detection device.

### BACKGROUND INFORMATION

In general a power distribution grid delivers electricity from a power plant to a residential, commercial or industrial building. Most electrical systems in residential, commercial and industrial applications include a panelboard switchgear for receiving electrical power from a utility source and then distributing electrical power to one or more branch circuits.

Power is routed through overcurrent devices, including by way of non limiting example circuit breakers, circuit interrupters, or fuses to designated branch circuits supplying one or more loads. Circuit breakers are typically used in electrical systems to interrupt and cut off the electrical current supplied to the loads once predefined current limits are surpassed.

A circuit breaker interrupts current supplied to an electric circuit due to a a current overload or ground fault. The current overload condition results when current exceeds the continuous rating of the breaker for a time interval determined by the trip curve or in response to an instantaneous load that exceeds a predefined threshold. The ground fault trip condition is created by an imbalance of current flowing between a line conductor and a neutral conductor, such as by a current path to ground, or sometimes by an arcing fault to ground.

Arcing faults are defined as current path through ionized gas between two ends of a broken conductor, between two conductors supplying a load, or between a conductor and ground. Arcing faults are characterized by low and erratic current flow. Arcing faults may be undetected by standard circuit breakers, because the current flow may be below the breaker's tripping threshold. Upon occurrence of an arcing fault, branch or load impedance may cause the current levels to be reduced to a level below the trip curve setting of the circuit breaker, causing the arcing fault condition to be undetected by a circuit breaker. In addition, an arcing fault which does not contact a grounded conductor or other grounded point will not trip a ground fault protected circuit.

There are many conditions which may cause an arcing fault. For example, corroded, worn, or aged wiring or insulation, loose connections, wiring damaged by nails or staples through the insulation, and electrical stress caused by repeated overloading, lightening striking, etc. Arcing faults can cause fire if combustible materials are in proximity to the arcing zone.

Arcing fault detection systems or arcing fault circuit interrupters (AFCI) known in the art generally monitor current passing through a line conductor of a branch circuit, process the monitored information to detect whether characteristics of the line current represent the occurrence of an arcing fault, and perform an operation if an arcing fault is detected. The operation may include opening contacts of a circuit breaker (“tripping” the circuit breaker) or enunciating the arc fault condition through a communicatory device. (e.g. alarm, light, or enunciate or communication signal to an electronic control or remote monitoring device).

Therefore, there is a need for a simple and effective method to facilitate the testing of an arcing fault circuit interrupter in a branch circuit.

Among the disadvantages associated with known arc fault testers is that they are large and difficult to transport to sites and require the additional hardware, such as a computer, to generate a set of pattern waveforms and circuitry to simulate an arc-like waveform. These devices were considered too large, heavy, cumbersome and expensive for field usage. Therefore, there has also been a need for a person-portable device to test arc fault detectors.

Once an AFCI breaker has been installed in a house or other building, it may be necessary to perform a variety of field tests to ensure that the unit is properly connected to the local power circuit and further to ensure that the AFCI breaker is operating properly. For example, an electrician installing an AFCI breaker in a branch circuit may wish to verify that the AFCI breaker is capable of detecting arcs for that branch. Therefore, there has also been a need of a person-portable device to test arc fault detectors after they have been installed in the field. Many existing ground fault circuit interrupters (GFCI) testing devices do not conveniently enable an electrician on site in a house or other building to determine whether the AFCI will trip.

Similarly, in the past there is no convenient method for sales personnel in the field to conduct tests and demonstrations at tradeshows or customers sites to show consumers how an AFCI product works.

Another disadvantage associated with conventional arc fault testers is that there are no methods or apparatus to generate true 120 volt arc fault current that is repeatable and consistent fault for tripping an AFCI breaker. In the past, testers have used voltages higher than 120 V, because more power is required to generate simulations for an arc fault either via a computer or complicated circuitry.

Accordingly, it is an object of the present invention to overcome and mitigate at least one of the foregoing disadvantages.

### SUMMARY OF INVENTION

It is therefore the present invention to provide an improved arc fault tester device for use in testing the operation of an AFCI breaker.

It is a further object of this invention to provide an arc fault testing device that is easily portable and small in size. The present invention uses off-the-shelve components and operates using a simple circuit to drive a contact relay. The use of computers or complex analog circuits is not required.

It is also an object of this invention to provide an arc fault tester that is compatible with all competitor circuit breakers and AFCI devices.

It is also an object of this invention to provide an arc fault tester that is connected to a 120 voltage outlet AC power supply.

The present invention is directed towards an apparatus that is readily portable and has the capability to generate a true arc signal that will trip an AFCI breaker for testing the operation of an arc fault detection device.

In accordance with one aspect of this invention, an apparatus for testing an arcing fault interruption comprising an arc generator control circuit including, an arc fault signal generator for generating an oscillating arc signal, and a contact relay coupled to and energized by the arc fault signal generator; a powered load coupled to the contact relay and a power source, so that an arcing current is generated upon oscillation of contacts within the relay; and a device under test receptacle coupled to the power load and the arc generator control circuit for selective electrical coupling to an arc detection device.

In accordance with another aspect of this invention, a method for testing arcing fault interruption where the method comprises generating an arc current by selectively oscillating contacts of a relay that is coupled to a powered circuit including load, and a device under test receptacle having an arc detection device coupled thereto.

In accordance with another aspect of this invention, a method to generate an arc fault where the method comprises selectively oscillating contacts of a relay that is coupled to a powered circuit.

In accordance with another aspect of this invention, a method for testing arcing fault interruption where the method comprises generating an arc fault current by energizing an operational amplification circuit to amplify a driving signal originating in an oscillator circuit, energizing a pre-amplification state circuit to amplify the driving signal sent through the operational amplification circuit, energizing a contact relay at a predetermined frequency to create an arc fault current, and determining whether the device under test detected the arc fault current.

### BRIEF DESCRIPTION OF DRAWINGS

FIG. 1 is a block diagram of the tester

FIG. 2 is a block diagram of the tester demonstration embodiment (portable scenario)

FIG. 3 is a block diagram of the tester embodiment (use in dwelling)

FIG. 4 is schematic circuit diagram of the tester

FIG. 5a) perspective view of hand held device

FIG. 5b) perspective view of a housing module which may house a the testing device

### DETAILED DESCRIPTION OF DRAWINGS

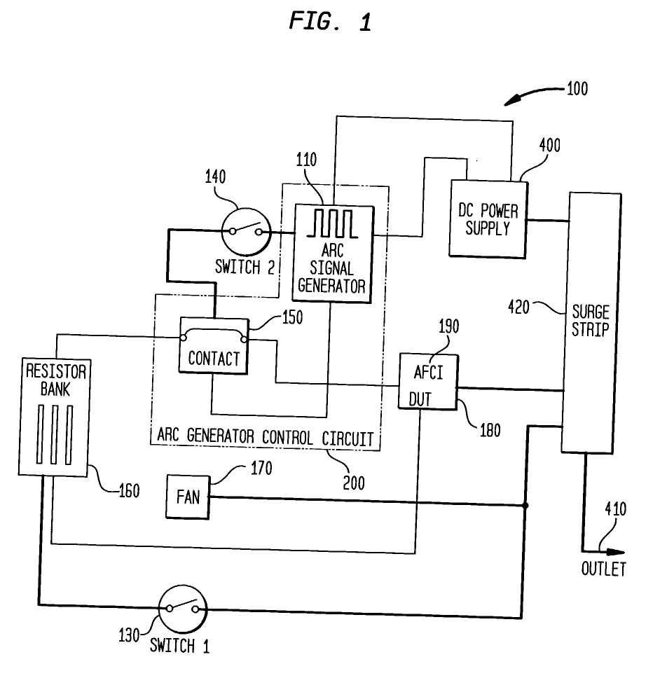

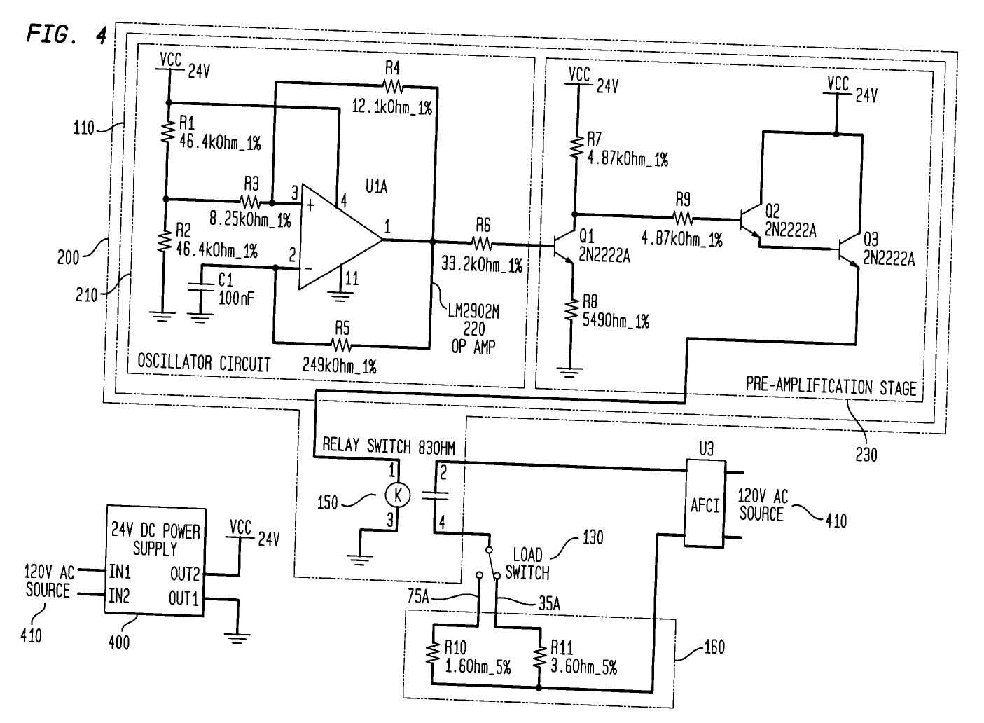

Referring to FIGS. 1 and 4, AFCI test apparatus 100 comprises an arc signal generator circuit 110, that includes an operational amplifier 220 and a preamplification stage 230. In this embodiment, DC power supply 400 powered by AC power source 410, power collectively the AFCI test apparatus 100.

A load selector switch 130, a power switch 140, a contact relay 150, a resistor bank 160, a cooling fan 170, a device under test (DUT) receptacle 180, which can be configured to receive an AFCI 190, and a power surge strip 420, wired as shown in FIGS. 1 and 4, complete the components of the tester of this embodiment. For ease of reference, arc generator control circuit 200 can also be used to describe the combination of the arc signal generator circuit 110, and the contact relay 150.

Referring to FIG. 1, an operator connects the load path to the DUT receptacle 180 and select a load, 35A or 75A, created by the resistor bank 160 using load selector switch 130. Prior to energizing the AFCI 190 and DUT receptacle 180, the operator turns on the tester using power switch 140.

Once the AFCI testing apparatus 100 is turned on, an arc fault current is generated by the arc generator control circuit 200. This is accomplished when the arc signal generator circuit 110 is powered by DC power supply 400. The oscillator circuit 210 begins to generate a driving signal which is then amplified by the pre-amplifier stage 230 that creates an arc fault current signal. This arc fault current signal energizes contact relay 150 at a predetermined frequency. As shown in FIG. 4 of the schematic circuit diagram, oscillator circuit 210 is designed to drive a contact relay 150. Oscillator circuit 210 comprises resistors R1, R2, R3, R4, R5, R6, and C1 and U1A LM2902 operational amplifier 12, A suitable, but not required, operational amplifier is a model sold by National Semiconductors. Current pre-amplification stage 230 comprises R7, R8, R9 Q1, Q2, and Q3. Operational amplifier 220 and current pre-amplification stage 230 amplify the signal produced by oscillator circuit 210. This stage is important for this embodiment because oscillator circuit 210 alone does not provide enough power to drive the contact relay 150, therefore, additional amplification of the signal is required.

Others skilled in the art may wish to select different components and circuitry then shown in this embodiment for generating the arc fault current signal that is needed to drive a contact relay. A load selector switch 130 can be set two either of two load settings 35 A or 75 A. Once the load selector switch 130 has been set and the DC power supply 400 has been connected to the AC power source 410 by means of a power surge strip 420, the AFCI test apparatus 100 can be turned on by power switch 140.

Arc signal generator circuit 110 is operational as soon as DC power supply 400 is connected. Oscillator circuit 210, operational amplification 220, and pre-amplification state 230 drive contact relay 150, causing at a predetermined frequency, causing contact relay 150 to open and close under a 120 v selected load (in this example 35A or 75A). This enables contact relay 150 to generate an arc fault current. The oscillation circuit frequency range used and tested is desirably between 10-20 hz with an ideal frequency of 11 hz. Others skilled in the art may choose a different frequency range. Once contact relay 150 has been excited, causing the contact relay 150 to open and close and load switch 130 has been engaged, resistor bank 160 will supply the appropriate load to pull a desired amount of current necessary to generate an arc within the relay. The resistor bank 160 consists of a series of resistors connected to work as a load for the DUT receptacle 180 and AFCI 190 coupled therein. Cooling fan 170 can dissipate the heat produced by the resistor bank 160 while the test is being performed on DUT receptacle 180 and AFCI 190 coupled therein.

At this point, if the AFCI 190 internal contacts located within DUT receptacle 180 are not closed, the operator will not see any arcs coming from the contact relay 150 because the arc path is not energized (open circuit condition). Once the AFCI 190 contacts are closed, the contact relay 150 will chatter and create arcs. The arc will be visible by the display of a small spark and a small noise. If the load selected by the load selector switch 30 is valued at 75A, the DUT receptacle 180 will trip as mandated by UL 1699. This will show that the AFCI 190 located within the DUT receptacle 180 is operating correctly as it is sensing the arc fault. If the load selected by the load selector switch 130 is valued at 35 A, the circuit breaker will not trip as the load value is within its normal operational range of the above identified UL test procedure and this will mean that the AFCI 190 located within DUT receptacle 180 is operating in accordance with the test standard.

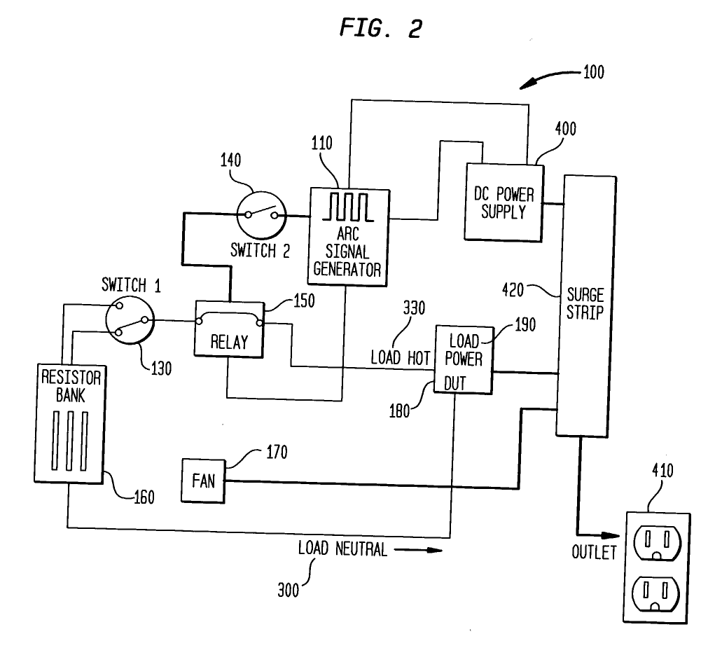

Referring to FIG. 2, the demonstration embodiment is used in conferences and trade show expositions. The operation follows the same description for the tester embodiment operation above. Here, however, the AFCI 190 is positioned where the load hot wire 330 connects the AFCI 190 and DUT receptacle 180 to the power surge strip 420.

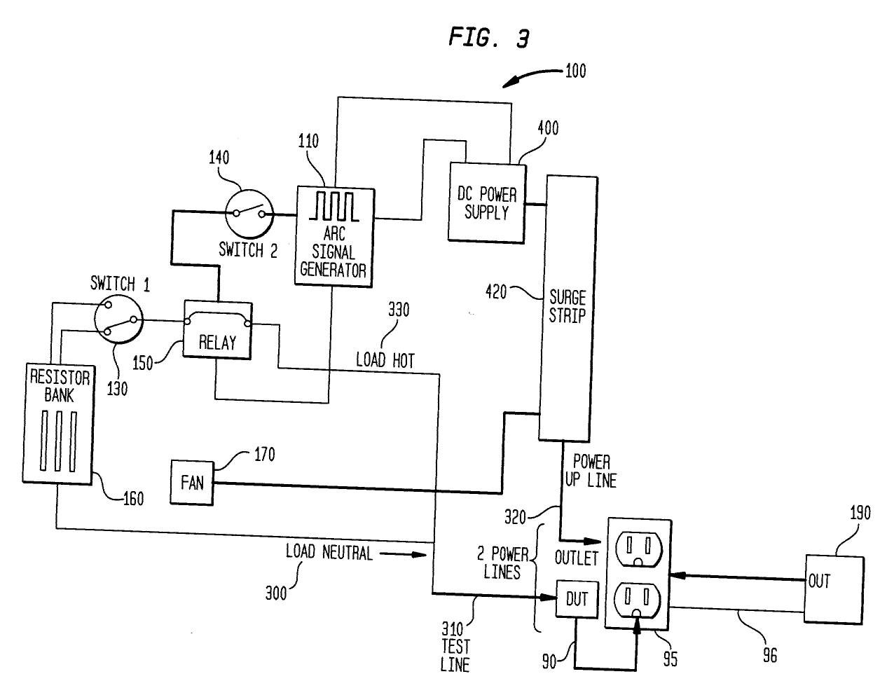

Referring to FIG. 3, this testing embodiment reflects a device that connects to an AC power outlet 410 to test an AFCI 190 already installed in a dwelling. The operation follows the same description set out above. Here however, the tester connects two power lines, test line 310 and power up line 320, to the AC Power Supply 410. Test line 310 is to power the circuitry of the test apparatus 100 and power up line 320 is to connect the AFCI 190 to the arcing load. It is important to note that test line 310 is comprised of two separate lines, load neutral line 300 and load hot line 330.

While the previously described shows application for alternating current electrical system arc detector devices, the tester can be configured to test direct current (DC) arc detector devices by substitution of a DC power source for AC power source 410. In DC applications, it may be desirable to change the arc signal generator 110 frequency and the load resistance of resistor bank 160.

The AC power source 410 comprises an outlets standard 120 V AC, 60 Hz. The DC power supply 400 comprises an off-the shelf tunable 24 V DC power supply that provides power for the oscillator circuit 110. The AC power source 410 supplies power to the DUT receptacle 180 and the load hot line 330 and the load neutral line 300.

Load hot line 330 (Load Power) refers to the connection from the DUT receptacle 180 to the power surge strip 420. The load neutral line 300 refers to the lower potential coming from the resistor bank 160 to the DUT receptacle 180. The load neutral line 300 carries the higher potential power coming from the DUT receptacle 180. This design stresses the polarity arrangement of the design. Similarly, the contact relay 150 interrupts the load hot line 330 and the load neutral line 300 to create a true arc fault.

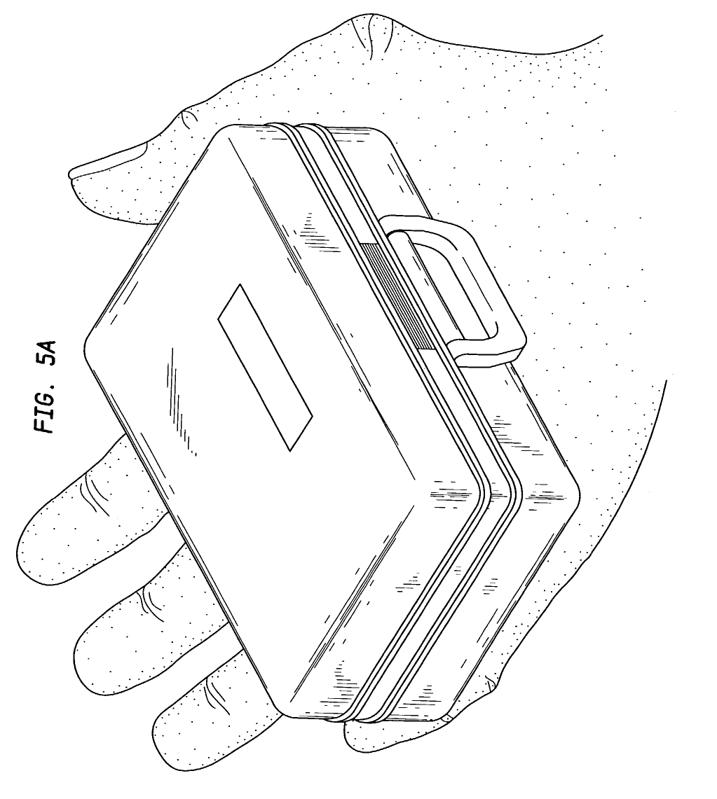

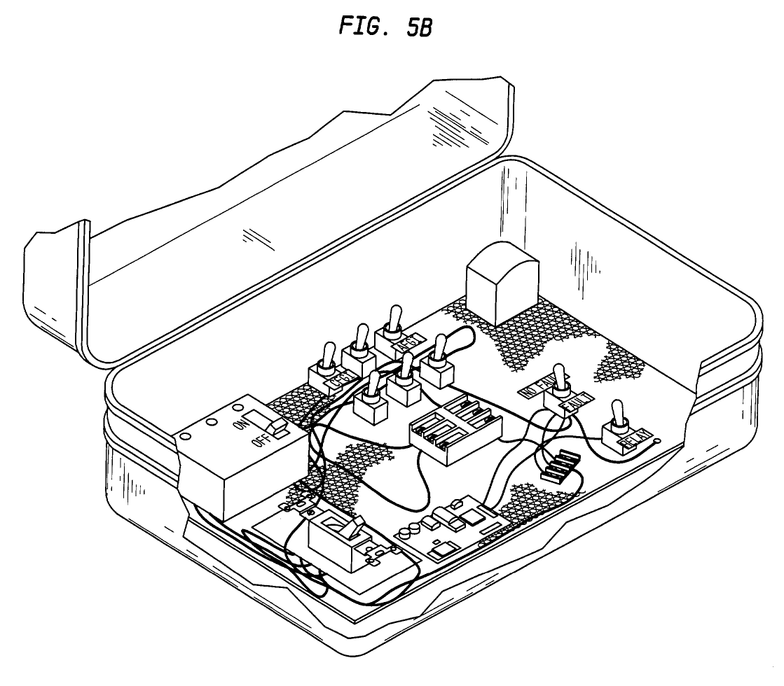

Referring to FIG. 5a, a testing apparatus 100 is enclosed in a hand held housing. There are several other enclosure embodiments that can be used including a hand held tester device.

It should be noted that the DUT receptacle 180 show in FIGS. 1-3 comprises a circuit breaker connector stab assembly used in the in electrical system panel boards so that it is capable of receiving AFCI 190 in its internal mounting environment. DUT receptacle 180 can also be configured to retain other configurations of arc fault circuit devices, such as by use of any desired electrical connector known in the art. DUT receptacle 180's functional purpose is to enable electrical coupling of a selected arc detection device to the arc generator control circuit 200 and resistor bank 160. In the embodiment of FIG. 3, the DUT receptacle 180 is an electrical receptacle plug that is inserted into a wired device outlet 95. In the manner the tester 100 is in electrical communication with the installed wired circuit 96 and AFCI 190 that protects the circuit. The arc generated in the tester 100 is propagated to the circuit 96.

While the present invention has been disclosed with reference to certain embodiments, numerous modifications, alterations, and changes to the described embodiments are possible without departing from the sphere and scope of the present invention. Accordingly, it is intended that the present invention not be limited to the described embodiments and equivalents thereof.

1) An apparatus for testing an arcing fault detector device, comprising:
an arc generator control circuit including,
an arc fault signal generator for generating an oscillating arc signal, and
a contact relay coupled to and energized by the arc fault signal generator;
a powered load coupled to the contact relay and a power source, so that an arcing current is generated upon oscillation of contacts within the relay; and
a device under test receptacle coupled to the power load and the arc generator control circuit for selective electrical coupling to an arc detection device.

2) The apparatus of claim 1, wherein the contact relay opens and closes at a predetermined frequency.

3) The apparatus of claim 2, wherein the predetermined frequency ranges between 10-20 hz.

4) The predetermined frequency of claim 3, wherein the contact relay opens and closes with an optimum frequency of 11 hz.

5) The apparatus of claim 1, wherein the arc generator control circuit comprises an operational amplifier oscillator.

6) The apparatus of claim 1, wherein the arc generator control circuit is powered by a DC power supply.

7) The apparatus of claim 1, wherein a device under test is powered by an AC power supply.

8) The apparatus of claim 1, wherein a load hot line and a load neutral line is powered by the AC power supply.

9) The apparatus of claim 1, wherein the AC outlet power supply comprises an outlet standard 120 V AC, 60 Hz.

10) The apparatus of claim 1, further comprising a selective load of at least two states and a load-selector switch coupled to the load.

11) The apparatus of claim 10, wherein the load-selector switch has a first position that selects to 75 A load.

12) The apparatus of claim 10, wherein the load-selector switch has a second position that selects a 35 A load.

13) The apparatus of claim 1, further comprising a transportable housing for containing the apparatus for testing the arcing fault detector device.

14) The apparatus of claim 13, wherein the transportable housing is shaped and sized as a hand held device.

15) The apparatus of claim 1, further comprising a cooling device for dissipating heat.

16) The apparatus of claim 15, wherein the cooling device is a fan.

17) A method for testing arcing fault interruption, the method comprising:
generating an arc current by selectively oscillating contacts of a relay that is coupled to a powered circuit including load, and a device under test receptacle having an arc detection device coupled thereto.

18) The method of claim 17, wherein the contacts relay is oscillated at a predetermined frequency range between 10-20 hz.

19) The method of claim 17, wherein the contact relay opens and closes with an optimum frequency of 11 hz.

20) The method of claim 17, further comprising a selective load of at least two states and a load-selector switch coupled to the load.

21) The method of claim 17, wherein the load-selector switch has a first position that selects 75 A load.

22) The method of claim 17, wherein the load-selector switch has a second position that selects 35 A load.

23) A method to generate an arc fault, method comprising:
selectively oscillating contacts of a relay that is coupled to a powered circuit.

24) The method of claim 23, wherein the contacts of the relay are oscillated at predetermined frequency ranges between 10-20 hz.

25) The method of claim 23, wherein the contact relay opens and closes with an optimum frequency of 11 hz.

26) A method for testing arcing fault interruption, the method comprising:
generating an arc fault current by energizing an operational amplification circuit to amplify a driving signal originating in an oscillator circuit;
energizing a pre-amplification stage circuit to amplify the driving signal sent through the operational amplification circuit;
energizing a contact relay at a predetermined frequency to create an arc fault; and
determining whether the device under test detects the arc fault current.

27) The method of claim 26, wherein the predetermined frequency ranges between 10-20 hz.

28) The method of claim 26, wherein the contact relay opens and closes with an optimum frequency of 11 hz.

29) An apparatus for testing an arcing fault detector device, comprising:
an arc generator control circuit means for generating an arc signal;
a contact relay means for generating an arc therein, coupled to and energized by the arc generator control circuit means;
a powered load coupled to the contact relay means, so that the contact relay means generates an arcing current; and
a device under test receptacle coupled to the power load and the arc generator control circuit means for selective electrical coupling to an arc detection device.

30) The apparatus of claim 29, wherein the contact relay means opens and closes at a predetermined frequency.

31) The apparatus of claim 29, wherein the predetermined frequency ranges between 10-20 hz.

32) The predetermined frequency of claim 30, wherein the contact relay means opens and closes with an optimum frequency of 11 hz.

33) The apparatus of claim 29, wherein the arc generator control circuit means comprises an operational amplifier oscillator.

34) The apparatus of claim 29, wherein the arc generator control circuit means is powered by a DC power supply.

35) The apparatus of claim 29, wherein a device under test is powered by an AC power supply.

36) The apparatus of claim 29, wherein a load hot line and a load neutral line is powered by the AC power supply.

37) The apparatus of claim 29, wherein the AC outlet power supply comprises an outlet standard 120 V AC, 60 Hz.

38) The apparatus of claim 29, further comprising a selective load of at least two states and a load-selector switch coupled to the load.

39) The apparatus of claim 40, wherein the load-selector switch has a first position that selects to 75 A load.

40) The apparatus of claim 40, wherein the load-selector switch has a second position that selects a 35 A load.

41) The apparatus of claim 29, further comprising a transportable housing for containing the apparatus for testing the arcing fault detector device.

42) The apparatus of claim 41, wherein the transportable housing is shaped and sized as a hand held device.

43) The apparatus of claim 29, further comprising a cooling device for dissipating heat.

44) The apparatus of claim 43, wherein the cooling device is a fan.
